(19) United States
(12) Patent Application Publication
(10) Pub. No.: US 2026/0157194 A1
(43) Pub. Date: Jun. 4, 2026

(54) SEMICONDUCTOR PACKAGE INCLUDING PACKAGE SUBSTRATE AND SEMICONDUCTOR CHIPS

(71) Applicant: Samsung Electronics Co., Ltd., Suwon-si (KR)

(72) Inventors: Yonghyun Kim, Suwon-si (KR); Hyunseok Kim, Suwon-si (KR); Geunwoo Kim, Suwon-si (KR); Wonil Seo, Suwon-si (KR); Taejun Jeon, Suwon-si (KR)

(21) Appl. No.: 19/388,186

(22) Filed: Nov. 13, 2025

(30) Foreign Application Priority Data
Dec. 3, 2024 (KR) 10-2024-0177435

(51) Int. Cl. H01L 23/538; H01L 23/00; H01L 23/13; H01L 23/31; H01L 25/065

(52) U.S. Cl. CPC H10W 70/611; H10W 70/68; H10W 74/114; H10W 90/00; H10W 90/401; H10W 72/07354; H10W 72/347; H10W 72/877; H10W 74/15; H10W 90/20; H10W 90/24; H10W 90/721; H10W 90/724; H10W 90/732; H10W 90/734

(57) ABSTRACT

A semiconductor package includes a package substrate, a semiconductor chip stack, an interposer and a molding member. The semiconductor chip stack may include a first semiconductor chip on the package substrate and second semiconductor chips stacked on the first semiconductor chip in a vertical direction. End portions in a first horizontal direction of the second semiconductor chips may not be aligned with each other in the vertical direction. The interposer may be disposed between the package substrate and the semiconductor chip stack, and may at least partially overlap the semiconductor chip stack in the first horizontal direction and include a wiring structure. The molding member may be disposed on the package substrate, and may cover the semiconductor chip stack and the interposer. The package substrate may include a hole extending in the vertical direction through a portion of the package substrate between the first semiconductor chip and the interposer. The molding member may at least partially fill the hole.

### CROSS-REFERENCE TO RELATED APPLICATION

This application claims priority under 35 U.S.C. § 119 to Korean Patent Application No. 10-2024-0177435, filed on Dec. 3, 2024 in the Korean Intellectual Property Office (KIPO), the contents of which are herein incorporated by reference in their entirety.

### BACKGROUND

### 1. Field

Example embodiments relate to a semiconductor package. More particularly, example embodiments relate to a semiconductor package including a plurality of semiconductor chips stacked on a substrate.

### 2. Description of the Related Art

In a multi-chip package including a plurality of semiconductor chips stacked on a package substrate, chip pads on each of the semiconductor chips and substrate pads on the package substrate may be electrically connected to each other by bonding wires. Due to the space of the bonding wires, the size of the multi-chip package may increase.

### SUMMARY

Example embodiments provide a semiconductor package having enhanced electrical characteristics.

According to example embodiments, a semiconductor package includes a package substrate, a semiconductor chip stack, an interposer and a molding member. The semiconductor chip stack may include a first semiconductor chip on the package substrate and second semiconductor chips stacked on the first semiconductor chip in a vertical direction. End portions in a first horizontal direction of the second semiconductor chips may not be aligned with each other in the vertical direction. The interposer may be disposed between the package substrate and the semiconductor chip stack, and may at least partially overlap the semiconductor chip stack in the first horizontal direction and include a wiring structure. The molding member may be disposed on the package substrate, and may cover the semiconductor chip stack and the interposer. The package substrate may include a hole extending in the vertical direction through a portion of the package substrate between the first semiconductor chip and the interposer. The molding member may at least partially fill the hole.

According to example embodiments, a semiconductor package includes a package substrate, a first conductive bump, a semiconductor chip stack, a second conductive bump, an interposer, a first underfill, a second underfill and a molding member. The first conductive bump may be disposed on the package substrate. The semiconductor chip stack may include a logic chip, memory chips, a first adhesion layer and a second adhesion layer. The logic chip may be disposed on the first conductive bump. The memory chips may be stacked on the logic chip in a vertical direction. End portions in a horizontal direction of the memory chips may not be aligned with each other in the vertical direction. The first adhesion layer may be disposed between and contact the logic chip and a lowermost one of the memory chips. The first adhesion layer may include a first adhesive material. The second adhesion layer may be disposed between and contact the memory chips. The second adhesion layer may include a second adhesive material different from the first adhesive material. The second conductive bump may be spaced apart from the first conductive bump in the horizontal direction on the package substrate. The interposer may be disposed between the second conductive bump and the semiconductor chip stack, and may at least partially overlap the semiconductor chip stack in the horizontal direction and include a wiring structure. The first underfill may be disposed between the package substrate and the semiconductor chip stack, and may cover a sidewall of the first conductive bump. The second underfill may be disposed between the package substrate and the interposer, and may cover a sidewall of the second conductive bump. The molding member may be disposed on the package substrate and cover the semiconductor chip stack \, the interposer, and the first and second underfills.

According to example embodiments, a semiconductor package includes a package substrate structure, a first conductive bump on the package substrate structure, a semiconductor chip stack structure, a first underfill member, a second conductive bump, an interposer, a second underfill member, a third conductive bump and a molding member. The first conductive bump may be disposed on the package substrate structure. The semiconductor chip stack structure may include a first semiconductor chip, second semiconductor chips, a first adhesion layer and a second adhesion layer. The first semiconductor chip may be disposed on the first conductive bump. The second semiconductor chips may be stacked on the first semiconductor chip in a vertical direction. End portions in a horizontal direction of the second semiconductor chips may not be aligned with each other in the vertical direction. The first adhesion layer may be disposed between and contact the first semiconductor chip and a lowermost one of the second semiconductor chips. The second adhesion layer may be disposed between and contact the second semiconductor chips. The first underfill member may be disposed between the package substrate structure and the semiconductor chip stack structure, and may cover a sidewall of the first conductive bump. The second conductive bump may be spaced apart from the first conductive bump in the horizontal direction on the package substrate structure. The interposer may be disposed between the second conductive bump and the semiconductor chip stack structure, and may at least partially overlap the semiconductor chip stack structure in the horizontal direction and include a wiring structure. The second underfill member may be disposed between the package substrate structure and the interposer, and may cover a sidewall of the second conductive bump. The third conductive bump may be disposed between the interposer and the semiconductor chip stack structure. The molding member may be disposed on the package substrate structure, and may cover the semiconductor chip stack structure, the interposer, the first and second underfill members, and the third conductive bump. The package substrate structure may include a hole extending in the vertical direction through a portion of the package substrate structure between the first semiconductor chip and the interposer. The molding member may at least partially fill the hole.

In the semiconductor package in accordance with example embodiments, the interposer may be disposed in the space between the semiconductor chip stack structure and the package substrate structure and electrically connect the semiconductor chip stack structure and the package substrate structure. Thus, the semiconductor package may have a reduced size and an enhanced integration degree.

Additionally, each of the semiconductor chips included in the semiconductor chip stack structure may be independently connected to the package substrate structure through the interposer, so that the number of input/output (I/O) circuits may increase, and the circuit length may decrease. Accordingly, the semiconductor package may have enhanced electrically connected to characteristics.

### BRIEF DESCRIPTION OF THE DRAWINGS

FIGS. 1 and 2 are a cross-sectional view and a bottom view, respectively, illustrating a semiconductor package in accordance with example embodiments.

FIGS. 3 to 6 are cross-sectional views illustrating a method of manufacturing a semiconductor package in accordance with example embodiments.

FIG. 7 is a cross-sectional view illustrating a semiconductor package in accordance with example embodiments.

FIG. 8 is a bottom view illustrating a semiconductor chip stack structure and an interposer included in a semiconductor package in accordance with example embodiments.

### DETAILED DESCRIPTION OF EXAMPLE EMBODIMENTS

Hereinafter, example embodiments will be explained in detail with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively. Thus, a first material, layer, region, electrode, pad, pattern, structure or process discussed below in one section of the specification could be termed a second material, layer, region, electrode, pad, pattern, structure or process in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

Hereinafter, two directions crossing each other among horizontal directions that are substantially parallel to an upper surface of the substrate may be referred to as first and second directions D1 and D2, respectively, and a vertical direction substantially perpendicular to the upper surface of the substrate may be referred to as a third direction D3. In example embodiments, the first and second directions D1 and D2 may be substantially perpendicular to each other.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Items described in the singular herein may be provided in plural, as can be seen, for example, in the drawings. Thus, the description of a single item that is provided in plural should be understood to be applicable to the remaining plurality of items unless context indicates otherwise.

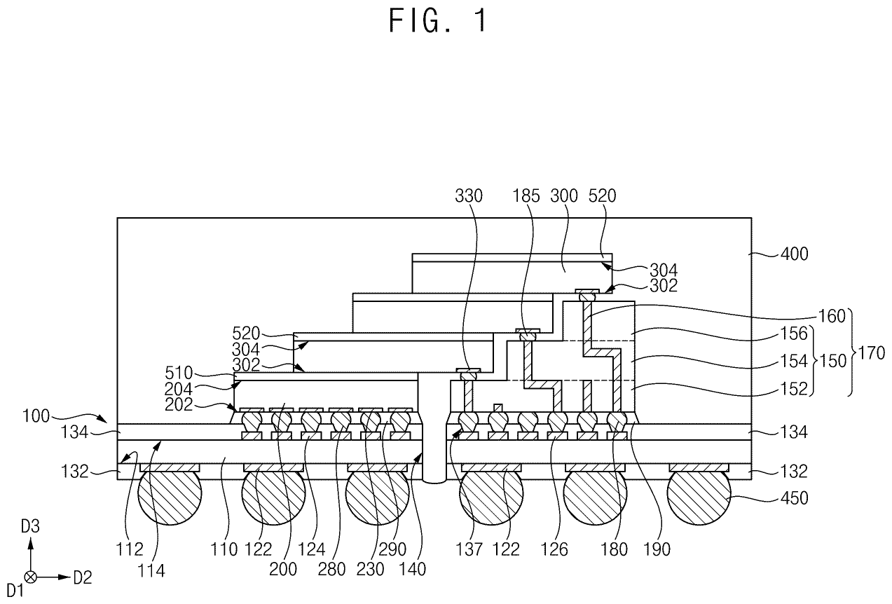

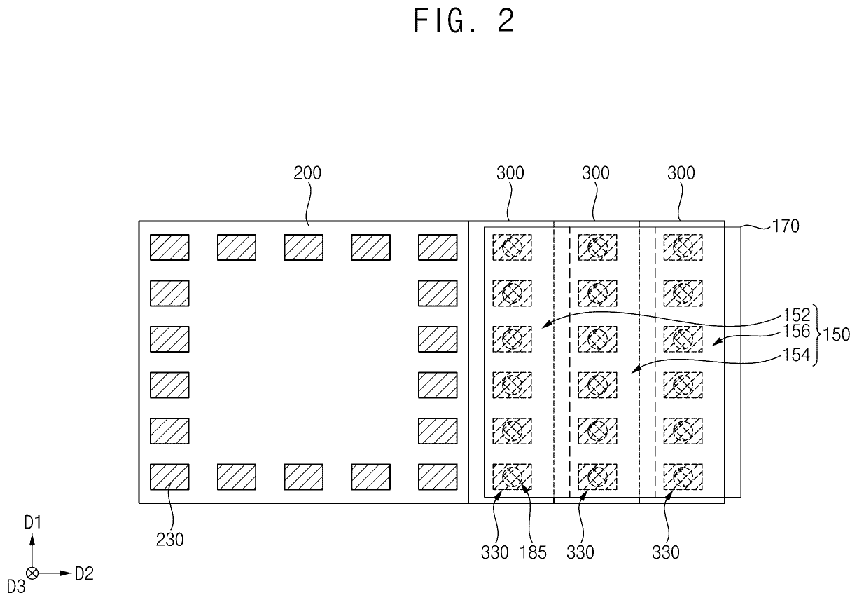

FIGS. 1 and 2 are a cross-sectional view and a bottom view, respectively, illustrating a semiconductor package in accordance with example embodiments. FIG. 2 is a bottom view illustrating a semiconductor chip stack structure and an interposer included in the semiconductor package, and does not show other elements.

Referring to FIGS. 1 and 2, the semiconductor package may include a package substrate structure 100 (e.g., package substrate), a semiconductor chip stack structure (e.g., semiconductor chip stack), an interposer 170, first to fourth conductive connection members 180, 185, 280 and 450, which may be connection terminals, first and second underfill members 190 and 290, first and second adhesion layers 510 and 520, and a molding member 400.

The package substrate structure 100 may be a printed circuit board (PCB).

In an example embodiment, the package substrate structure 100 may include a base structure 110 (e.g., a base) having first and second surfaces 112 and 114 opposite to each other in the third direction D3, first to third conductive pads 122, 124 and 126 on the first and second surfaces 112 and 114 of the base structure 110, a first protective layer 132 on the first surface 112 of the base structure 110, and a second protective layer 134 on the second surface 114 of the base structure 110.

In an example embodiment, the base structure 110 may include a core, first and second insulating interlayers on first and second and lower surfaces, respectively, of the core, and first and second wiring structures in the first and second insulating interlayers, respectively. The first conductive pad 122 may be disposed on a lower surface of the first insulating interlayer, and may be electrically connected to the first wiring structure, and each of the second and third conductive pads 124 and 126 may be disposed on an upper surface of the second insulating interlayer, and may be electrically to the second wiring structure. In example embodiments, a plurality of first conductive pads 122 may be spaced apart from each other in each of the first and second directions D1 and D2, a plurality of second conductive pads 124 may be spaced apart from each other in each of the first and second directions D1 and D2, and a plurality of third conductive pads 126 may be spaced apart from each other in each of the first and second directions D1 and D2.

The core may include, e.g., a mixture of glass fiber and epoxy, and each of the first and second insulating interlayers may include an organic insulating material, e.g., Ajinomoto build-up film (ABF). Each of the first and second wiring structures and each of the first to third conductive pads 122, 124 and 126 may include a conductive material, e.g., a metal, a metal nitride, a metal silicide, etc.

The first protective layer 132 may expose a lower surface of a portion of the first conductive pad 122, and the second protective layer 134 may expose an upper surface of a portion of each of the second and third conductive pads 124 and 126. Each of the first and second protective layers 132 and 134 may include, e.g., solder resist (SR).

Alternatively, the package substrate structure 100 may be a coreless substrate not including the core, and in this case, the package substrate structure 100 may include, e.g., insulating interlayers, wiring structures in the insulating interlayers, conductive pads electrically connected to the wiring structures, and protective layers on lower and upper surfaces of the insulating interlayers, respectively, and partially covering the conductive pads.

In example embodiments, the package substrate structure 100 may include a hole 140 (e.g., an opening) extending through the package substrate structure 100. In example embodiments, the hole 140 may extend in the first direction D1 to a given length.

The fourth conductive connection member 450 may be an external connection terminal disposed on a lower surface of the first protective layer 132 included in the package substrate structure 100, and may extend through the first protective layer 132 to contact a lower surface of the first conductive pad 122. The fourth conductive connection member 450 may include, e.g., a conductive ball or a conductive bump. In example embodiments, a plurality of fourth conductive connection members 450 may be spaced apart from each other in each of the first and second directions D1 and D2.

The semiconductor chip stack structure may include a first semiconductor chip 200 on the package substrate structure 100, a plurality of second semiconductor chips 300 stacked in the third direction D3 on the first semiconductor chip 200, the first adhesion layer 510 between the first semiconductor chip 200 and a lowermost one of the second semiconductor chips 300, and the second adhesion layer 520 between the second semiconductor chips 300.

FIG. 1 shows that the semiconductor chip stack structure includes three second semiconductor chips 300 stacked on the first semiconductor chip 200, however, the inventive concept is not limited thereto, and the semiconductor chip stack structure may include two or more than three second semiconductor chips 300.

In example embodiments, the first semiconductor chip 200 may include first and second surfaces 202 and 204 opposite to each other in the third direction D3, and a fourth conductive pad 230 may be disposed at a portion of the first surface 202 of the first semiconductor chip 200. In example embodiments, a plurality of fourth conductive pads 230 may be spaced apart from each other in each of the first and second directions D1 and D2. The first semiconductor chip 200 may have a shape of a rectangle in a plan view or in a bottom view.

The first semiconductor chip 200 may have an active layer adjacent to the first surface 202 thereof, and circuit patterns of a logic device may be disposed in the active layer and may be electrically connected to the fourth conductive pad 230. Thus, the first semiconductor chip 200 may include, e.g., a controller, and may also be referred to as a logic chip or a logic die.

The third conductive connection member 280 may be a connection terminal disposed between the second conductive pad 124 of the package substrate structure 100 and the fourth conductive pad 230 of the first semiconductor chip 200, and the second underfill member 290 may be disposed between the second protective layer 134 of the package substrate structure 100 and the first surface 202 of the first semiconductor chip 200, and may bond the second protective layer 134 and the first surface 202 to each other.

The third conductive connection member 280 may include a conductive ball or a conductive bump including, e.g., solder. In example embodiments, a plurality of third conductive connection members 280 may be spaced apart from each other in each of the first and second directions D1 and D2.

The second underfill member 290 may have a shape of a rectangle in a plan view or in a bottom view. The second underfill member 290 may include an adhesive material, e.g., epoxy, acryl, etc.

The first adhesion layer 510 may be attached to the second surface 204 of the first semiconductor chip 200. The first adhesion layer 510 may include, e.g., non-conductive paste (NCP) or non-conductive film (NCF).

In example embodiments, each second semiconductor chip 300 may include first and second surfaces 302 and 304 opposite to each other in the third direction D3, and a fifth conductive pad 330 may be disposed at a portion of the second semiconductor chip 300 adjacent to the first surface 302 thereof. In example embodiments, a plurality of fifth conductive pads 330 may be spaced apart from each other in each of the first and second directions D1 and D2. The second semiconductor chip 300 may have a shape of a rectangle in a plan view or in a bottom view.

In example embodiments, a lowermost one of the second semiconductor chips 300 may be bonded to an upper surface of the first adhesion layer 510 attached to the second surface 204 of the first semiconductor chip 200, and the first surface 302 of an upper one of the second semiconductor chips 300 may be bonded to the second adhesion layer 520 attached to the second surface 304 of a lower one of the second semiconductor chips 300.

The second adhesion layer 520 may also be attached to the second surface 304 of an uppermost one of the second semiconductor chips 300, however, the inventive concept is not limited thereto, and in some embodiments, the second adhesion layer 520 may not be attached to the second surface 304 of the uppermost one of the second semiconductor chips 300. In example embodiments, the second adhesion layer 520 may include die attach film (DAF).

In example embodiments, each second semiconductor chip 300 may have a planar area greater than a planar area of the first semiconductor chip 200. A planar area for each semiconductor chip may refer to an area along a plane within a region surrounded by outermost boundaries of the semiconductor chip when viewed from a direction perpendicular to the plane. In an example embodiment, a length in the second direction D2 of the second semiconductor chip 300 may be greater than a length in the second direction D2 of the first semiconductor chip 200. Though not shown, in the second direction D2, a sidewall (e.g., that extends along the first direction D1) of the lowermost one of the second semiconductor chips 300 may be aligned with a sidewall (e.g., that extends along the first direction D1) of the first semiconductor chip 200 in the third direction D3.

The second semiconductor chip 300 may have an active layer adjacent to the first surface 302 thereof, and circuit patterns of a memory device may be disposed in the active layer and may be electrically connected to the fifth conductive pad 330. The second semiconductor chip 300 may include, e.g., a DRAM device, an SRAM device, a flash memory device, etc., and may also be referred to as a memory chip or a memory die.

In example embodiments, the second semiconductor chips 300 may be arranged in a cascade shape or staircase shape. For example, the second semiconductor chips 300 may be stacked in the third direction D3, and may be offset with each other in the second direction D2. Thus, an end portion in the second direction D2 of each of the second semiconductor chips 300 may protrude in the second direction D2 from end portions in the second direction D2 of other ones of the second semiconductor chips 300 disposed thereunder, and may not overlap the end portions of other ones of the second semiconductor chips 300 in the third direction D3. A sidewall in the second direction D2 of each of the second semiconductor chip 300 (e.g., a sidewall extending in the first direction D1) may not be aligned with sidewalls in the second direction D2 of the other ones of the second semiconductor chips 300 disposed thereunder (e.g., sidewalls extending in the first direction D1). For example, from a plan view, outermost edges of each second semiconductor chip 300 opposite each other in the D2 direction may not be at the same location in the D2 direction as the location from the plan view of corresponding outermost edges of an adjacent second semiconductor chip 300.

The first conductive connection member 180 may be a connection terminal disposed between and contacting an upper surface of the third conductive pad 126 of the package substrate structure 100 and a lower surface of the interposer 170. The first underfill member 190 may be disposed between the second protective layer 134 of the package substrate structure 100 and the lower surface of the interposer 170, and may bond the second protective layer 134 and the lower surface of the interposer 170 to each other. In example embodiments, a plurality of first conductive connection members 180 may be spaced apart from each other in each of the first and second directions D1 and D2. In an example embodiment, the first underfill member 190 may have a shape of a rectangle in a plan view or in a bottom view.

The first conductive connection member 180 may include a conductive ball or a conductive bump including, e.g., solder. The first underfill member 190 may include an adhesive material, e.g., epoxy, acryl, etc.

The interposer 170 may be disposed on the first conductive connection members 180. In example embodiments, the interposer 170 may include an insulating interlayer structure 150 and a third wiring structure 160 (e.g., wiring network) in the insulating interlayer structure 150. The insulating interlayer structure 150 may include three insulating interlayers stacked in the third direction D3, for example, third to fifth insulating interlayers 152, 154 and 156.

However, the inventive concept is not limited thereto, and the insulating interlayer structure 150 may include more or less than three insulating interlayers. In example embodiments, the insulating interlayer structure 150 may include the same number of the insulating interlayers as the number of the second semiconductor chips 300 stacked in the third direction D3.

In example embodiments, the third insulating interlayer 152 may at least partially overlap the first semiconductor chip 200 in the second direction D2, the fourth insulating interlayer 154 may at least partially overlap the lowermost one of the second semiconductor chips 300 in the second direction D2, and the fifth insulating interlayer 156 may at least partially overlap one of the second semiconductor chips 300 that is disposed at a second level from below in the second direction D2.

In example embodiments, an end portion in the second direction D2 of the third insulating interlayer 152 at least partially overlaps the lowermost one of the second semiconductor chips 300 in the third direction D3, an end portion in the second direction D2 of the fourth insulating interlayer 154 at least partially overlaps the one of the second semiconductor chips 300 that is disposed at the second level from below in the third direction D3, and an end portion in the second direction D2 of the fifth insulating interlayer 156 at least partially overlaps the uppermost one of the second semiconductor chips 200 in the third direction D3.

In example embodiments, the third insulating interlayer 152 may have a planar area greater than a planar area of the fourth insulating interlayer 154, and the fourth insulating interlayer 154 may have the planar area greater than a planar area of the fifth insulating interlayer 156. A planar area for each insulating interlayer may refer to an area along a plane within a region surrounded by outermost boundaries of the insulating interlayer when viewed from a direction perpendicular to the plane. Thus, the insulating interlayer structure 150 may have a staircase shape including a plurality of steps, each of which may have a width that extends in the first direction D1, and be arranged to protrude beyond an adjacent step in the second direction D2. The insulating interlayer structure 150 may have a shape of, e.g., a rectangle in a plan view or in a bottom view.

The third wiring structure 160 may include, e.g., wirings, vias, conductive pads, etc., and may have a variety of layouts in the insulating interlayer structure 150. FIGS. 1 and 2 show some of the wirings and vias, and each of the wirings may extend in one or ones of the first to third directions D1, D2 and D3 to a given length.

The second conductive connection member 185 (e.g., connection terminal) may be disposed on an upper surface of the interposer 170. In example embodiments, a plurality of second conductive connection members 185 may be spaced apart from each other in the first direction D1 on each of the third to fifth insulating interlayers 152, 154 and 156, and may contact a portion of the third wiring structure 160 to be electrically connected thereto. The second conductive connection members 185 may contact lower surfaces of corresponding ones, respectively, of the fifth conductive pads 330 on the first surface 302 of the second semiconductor chip 300.

In example embodiments, the upper surface of the interposer 170 may be lower than an upper surface of the semiconductor chip stack structure. In an example embodiment, the lower surface of the interposer 170 may be substantially coplanar with a lower surface of the semiconductor chip stack structure.

In example embodiments, the package substrate structure 100 may include a hole 140 extending through the package substrate structure 100 in the third direction D3. For example, the hole 140 may extend in the first direction D1 through a portion of the package substrate structure 100 between sidewalls of the first and second underfill members 190 and 290 opposite to each other in the second direction D2. Thus, the hole 140 may not overlap the first or second underfill members 190 and 290, the first semiconductor chip 200 or the interposer 170 in the third direction D3.

The molding member 400 may be disposed on the package substrate structure 100, and may cover the semiconductor chip stack structure, the interposer 170, the first and second underfill members 190 and 290, and the first and second adhesion layers 510 and 520. The molding member 400 may also be disposed in the hole 140 extending through the package substrate structure 100, and may at least partially fill the hole 140. In an example embodiment, the molding member 400 may entirely fill the hole 140. The molding member 400 may include epoxy molding compound (EMC).

As illustrated below, the molding member 400 may fill well a space between the semiconductor chip stack structure and the interposer 170 and a space between the first and second underfill members 190 and 290 that are disposed under the semiconductor chip stack structure and the interposer 170, by the hole 140 extending through the package substrate structure 100, and no voids may remain in the above spaces. The molding member 400 may have a staircase, or zig-zag shape between the semiconductor chip stack structure and the interposer 170 that extends from the hole 140.

In the semiconductor package, the semiconductor chip stack structure may include the first semiconductor chip 200 and the second semiconductor chips 300 stacked on the first semiconductor chip 200 in a cascade shape, and thus a space may be formed between the package substrate structure 100 and the semiconductor chip stack structure. However, in example embodiments, the interposer 170 may be disposed in the space, and may electrically connect the semiconductor chip stack structure and the package substrate structure 100 to each other.

If the semiconductor chip stack structure and the package substrate structure 100 are electrically connected to each other by bonding wires, an additional space for the bonding wires are needed, which may increase horizontal and vertical sizes of the semiconductor package.

Additionally, each of the semiconductor chips that are stacked in the vertical direction and included in the semiconductor chip stack structure may not be electrically connected to the package substrate structure independently, but may be electrically connected to the package substrate structure through the bonding wires, and thus a plurality of semiconductor chips may be electrically connected to the package substrate structure through a single electrical path.

However, in example embodiments, instead of the bonding wires, the semiconductor chip stack structure and the package substrate structure 100 may be electrically connected to each other through the interposer 170 that may be disposed in the space between the semiconductor chip stack structure and the package substrate structure 100, so that the semiconductor package may have a reduced size and an enhanced integration degree.

The second semiconductor chips 300 as well as the first semiconductor chip 200 included in the semiconductor chip stack structure may be independently electrically connected to the package substrate through the interposer 170. Thus, the number of input/output (I/O) circuits between the first and second semiconductor chips 200 and 300 and the package substrate structure 100 may increase so as to implement wide input/output.

Further, each of the second semiconductor chips 300 may be electrically connected to the package substrate structure 100 not by the bent bonding wires but by the third wiring structure 160 including the wirings that may extend in a straight line in the interposer 170, so that the signal transmission speed between each of the second semiconductor chips 300 and the package substrate structure 100 may increase. Particularly, the signal transmission speed between upper ones of the second semiconductor chips 300 and the package substrate structure 100 may increase.

As a result, the semiconductor package including the interposer 170 may have enhanced electrical characteristics.

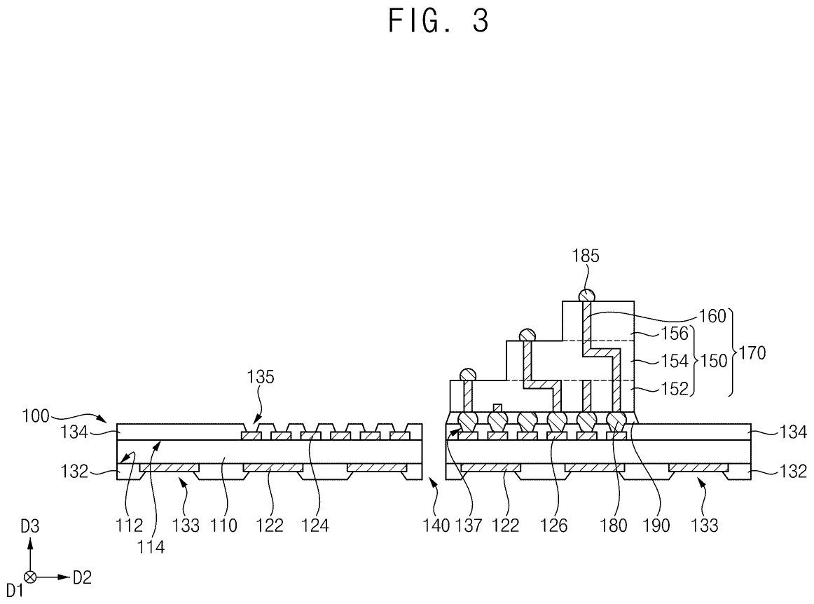

FIGS. 3 to 6 are cross-sectional views illustrating a method of manufacturing a semiconductor package in accordance with example embodiments.

Referring to FIG. 3, an interposer 170 may be mounted on a package substrate structure 100 through a first conductive connection member 180 therebetween, and a first underfill member 190 may be formed between the package substrate structure 100 and the interposer 170.

In example embodiments, the package substrate 100 may include a base structure 110 having first and second surfaces 112 and 114 opposite to each other in the third direction D3, first to third conductive pads 122, 124 and 126 on the first and second surfaces 112 and 114 of the base structure 110, a first protective layer 132 on the first surface 112 of the base structure 110 and having a first opening 133 at least partially exposing the first conductive pad 122, and a second protective layer 134 on the second surface 114 of the base structure 110 and having second and third openings 135 and 137 at least partially exposing the second and third conductive pads 124 and 126, respectively.

In an example embodiment, the base structure 110 may include a core, first and second insulating interlayers on first and second and lower surfaces, respectively, of the core, and first and second wiring structures in the first and second insulating interlayers, respectively. The first conductive pad 122 may be electrically connected to the first wiring structure, and each of the second and third conductive pads 124 and 126 may be electrically connected to the second wiring structure.

The first conductive connection member 180 may be formed by forming a conductive layer on the second protective layer 134 to contact an upper surface of the third conductive pad 126 exposed by the third opening 137, and performing a reflow process on the conductive layer.

The interposer 170 may be disposed on the first conductive connection members 180. In example embodiments, the interposer 170 may include an insulating interlayer structure 150 including third to fifth insulating interlayers 152, 154 and 156 sequentially stacked in the third direction D3 and a third wiring structure 160 in the insulating interlayer structure 150.

In example embodiments, the third insulating interlayer 152 may have a planar area greater than a planar area of the fourth insulating interlayer 154, and the fourth insulating interlayer 154 may have the planar area greater than a planar area of the fifth insulating interlayer 156. Thus, the insulating interlayer structure 150 may have a staircase shape including a plurality of steps, each of which may have a width extending in the first direction D1, and may be arranged in the second direction D2.

The third wiring structure 160 may include, e.g., wirings, vias, conductive pads, etc., and may have a variety of layouts in the insulating interlayer structure 150. FIG. 3 shows some of the wirings and vias, and each of the wirings may extend in one or ones of the first to third directions D1, D2 and D3 to a given length.

A second conductive connection member 185 may be disposed on an upper surface of the interposer 170. In example embodiments, a plurality of second conductive connection members 185 may be spaced apart from each other in the first direction D1 on each of the third to fifth insulating interlayers 152, 154 and 156, and may contact a portion of the third wiring structure 160 to be electrically connected thereto.

The first underfill member 190 may be disposed between an upper surface of the second protective layer 134 of the package substrate structure 100 and a lower surface of the interposer 170, and may cover a sidewall of the first conductive connection member 180.

In example embodiments, the package substrate structure 100 may include a hole 140 extending through the package substrate structure 100 in the third direction D3. For example, the hole 140 may extend in the first direction D1 at a region of the package substrate structure 100 adjacent to a sidewall in the second direction D2 of the first underfill member 190. The hole 140 may have an elongated shape in the first direction D1 to form a trench.

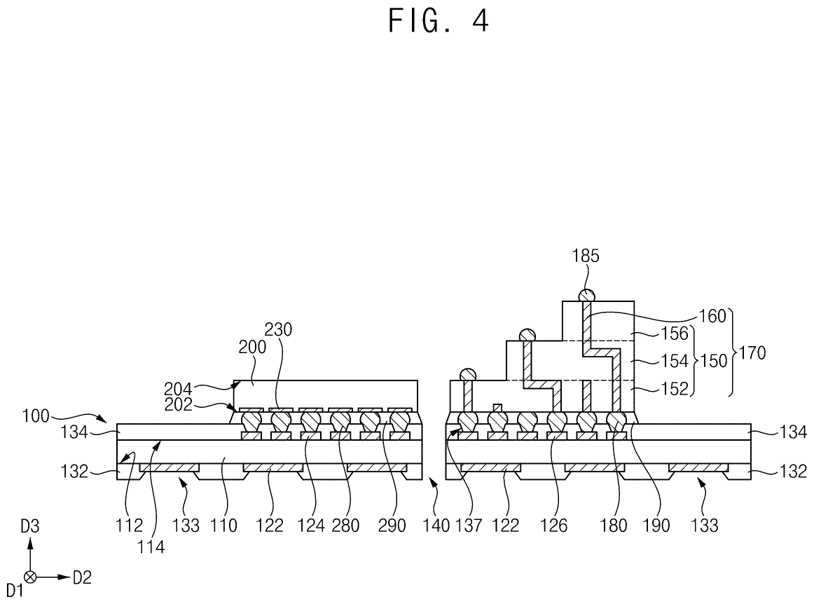

Referring to FIG. 4, a third conductive connection member 280 may be formed on a first surface 202 of a first semiconductor chip 200, the first semiconductor chip 200 may be flipped, the third conductive connection member 280 may be bonded to an upper surface of the second conductive pad 124 of the package substrate structure 100, and a second underfill member 290 may be formed between the package substrate structure 100 and the first semiconductor chip 200.

In example embodiments, the first semiconductor chip 200 may include first and second surfaces 202 and 204 opposite to each other in the third direction D3, and a fourth conductive pad 230 may be disposed at a portion of the first semiconductor chip 200 adjacent to the first surface 202 thereof.

The second underfill member 290 may be disposed between an upper surface of the second protective layer 134 of the package substrate structure 100 and the first surface 202 of the first semiconductor chip 200, and may cover a sidewall of the third conductive connection member 280. The second underfill member 290 may be formed on a region of the package substrate structure 100 adjacent to the hole 140 in the second direction D2.

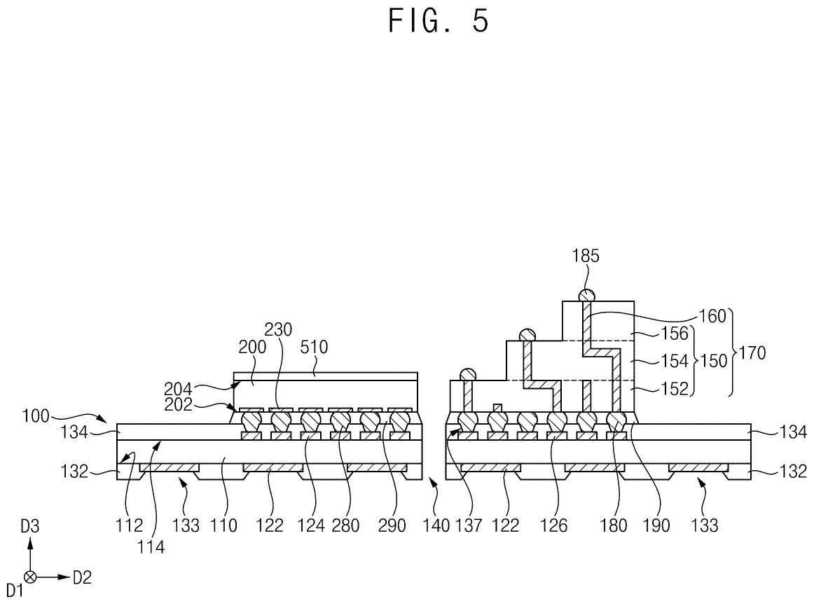

Referring to FIG. 5, a first adhesion layer 510 may be attached to the second surface 204 of the first semiconductor chip 200.

In example embodiments, the first adhesion layer 510 may include, e.g., NCP or NCF, and may be formed on the second surface 204 of the first semiconductor chip 200 by, e.g., a coating process.

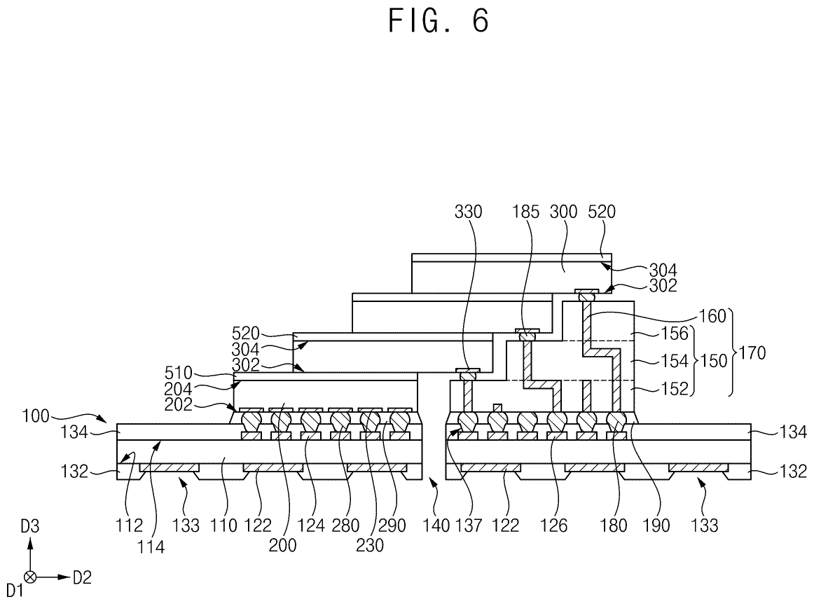

Referring to FIG. 6, a first one of second adhesion layers 520 may be attached to a second surface 304 of a first one of second semiconductor chips 300, and the first one of the second semiconductor chips 300 may bonded to the first adhesion layer 510 attached to the second surface 204 of the first semiconductor chip 200.

In example embodiments, each of the second semiconductor chips 300 may include a first surface 302 and the second surface 304 opposite to each other in the third direction D3, and a fifth conductive pad 330 may be disposed at a portion of each of the second semiconductor chips 300 adjacent to the first surface 302 thereof.

In example embodiments, each of the second semiconductor chips 300 may have a planar area greater than a planar area of the first semiconductor chip 200, and thus a portion of the first one of the second semiconductor chips 300, for example, an end portion in the second direction D2 of the first one of the second semiconductor chips 300 may not contact the first adhesion layer 510 attached to the first semiconductor chip 200.

In example embodiments, the second adhesion layer 520 may include DAF.

In example embodiments, the fifth conductive pad 330 of the first one of the second semiconductor chips 300 may contact an upper surface of a first one of the second conductive connection members 185 on an upper surface of the third insulating interlayer 152 of the interposer 170, and the first one of the second conductive connection members 185 may be bonded to the fifth conductive pad 330 by a reflow process.

A second one of second adhesion layers 520 may be attached to the second surface 304 of a second one of second semiconductor chips 300, and the second one of the second semiconductor chips 300 may be bonded to the first one of the second adhesion layers 520 attached to the second surface 304 of the first one of the second semiconductor chips 300. The fifth conductive pad 330 of the second one of the second semiconductor chips 300 may be bonded to an upper surface of a second one of the second conductive connection members 185 on an upper surface of the fourth insulating interlayer 154 of the interposer 170.

A third one of second adhesion layers 520 may be attached to the second surface 304 of a third one of second semiconductor chips 300, and the third one of the second semiconductor chips 300 may be bonded to the second one of the second adhesion layers 520 attached to the second surface 304 of the second one of the second semiconductor chips 300. The fifth conductive pad 330 of the third one of the second semiconductor chips 300 may be bonded to an upper surface of a third one of the second conductive connection members 185 on an upper surface of the fifth insulating interlayer 156 of the interposer 170.

Thus, a semiconductor chip stack structure including the first and second semiconductor chips 200 and 300 and the first and second adhesion layers 510 and 520 may be formed on the package substrate structure 100. In example embodiments, the second semiconductor chips 300 may be arranged in a cascade shape, and thus an end portion in the second direction D2 of each of the second semiconductor chips 300 may not overlap other second semiconductor chips 300 thereunder in the third direction D3.

Referring to FIGS. 1 and 2 again, a molding member 400 may be formed on the package substrate structure 100.

The molding member 400 may fill a space between a first structure including the semiconductor chip stack structure and the second underfill member 290 and the second structure including the interposer 170 and the first underfill member 190 and the hole 140 in the package substrate structure 100. In an example embodiment, the molding member 400 may entirely fill the hole 140.

If the package substrate structure 100 does not include the hole 140, the molding member 400 may not entirely fill the space between the first and second structures, and a void may be generated in the space. However, in example embodiments, as the hole 140 is formed in the package substrate structure 100, the hole 140 may provide a path for moving of the molding member 400 having fluidity, so that no void may be formed in the space and the molding member 400 may entirely fill the space.

The molding member 400 may fill the hole 140, and further may have a lower surface that is convex downwardly and lower than a lower surface of the first protective layer 132.

The package substrate structure 100 may be flipped, a conductive layer may be formed on the upper surface of the first conductive pad 122 exposed by the first opening 133, and a reflow process may be performed to form a fourth conductive connection member 450.

For example, a sawing process may be performed on the package substrate structure 100 and the molding member 400 to complete manufacturing the semiconductor package.

As illustrated above, the first and second semiconductor chips 200 and 300 may be arranged in a cascade shape on the package substrate structure 100 to form the semiconductor chip stack structure, and the interposer 170 may be interposed in the space between the package substrate structure 100 and the semiconductor chip stack structure through the first conductive connection member 180. Thus, when compared to a case in which the second semiconductor chips 300 are electrically connected to the package substrate structure 100 by a wire bonding process, the semiconductor package may have a reduced horizontal width and vertical thickness.

The interposer 170 may have various shapes according to the layout of the second semiconductor chips 300 included in the semiconductor chip stack structure, and the third wiring 160 may have various layouts.

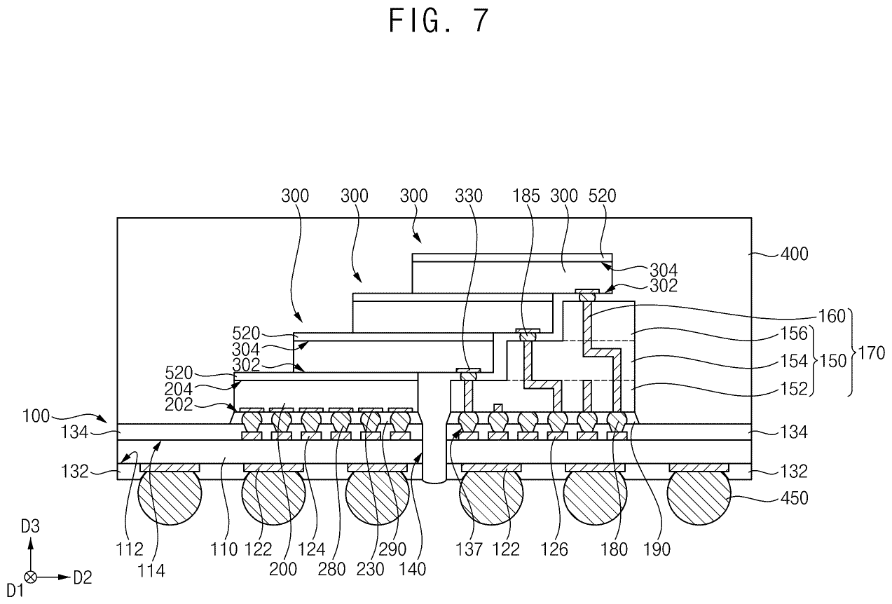

FIG. 7 is a cross-sectional view illustrating a semiconductor package in accordance with example embodiments, which may correspond to FIG. 1. This semiconductor package may be substantially the same as or similar to that of FIGS. 1 and 2, except for including the second adhesion layer instead of the first adhesion layer, and thus repeated explanations are omitted herein.

Referring to FIG. 7, the second adhesion layer 520, instead of the first adhesion layer 510, may be attached to the second surface 204 of the first semiconductor chip 200.

Particularly, when the processes illustrated with reference to FIG. 4 is performed, the third conductive connection member 280 may be formed on the first surface 202 of the first semiconductor chip 200 having the second adhesion layer 520 including, e.g., DAF on the second surface 204, the third conductive connection member 280 may be bonded to the upper surface of the second conductive pad 124 of the package substrate structure 100, and the second underfill member 290 may be formed between the package substrate structure 100 and the first semiconductor chip 200.

Thus, the process illustrated with reference to FIG. 5, for example, coating the first adhesion layer 510 including, e.g., NCP or NCF on the second surface 204 of the first semiconductor chip 200 may not be performed, and the second semiconductor chip 300 may be bonded to an upper surface of the second adhesion layer 520 attached to the second surface 204 of the first semiconductor chip 200.

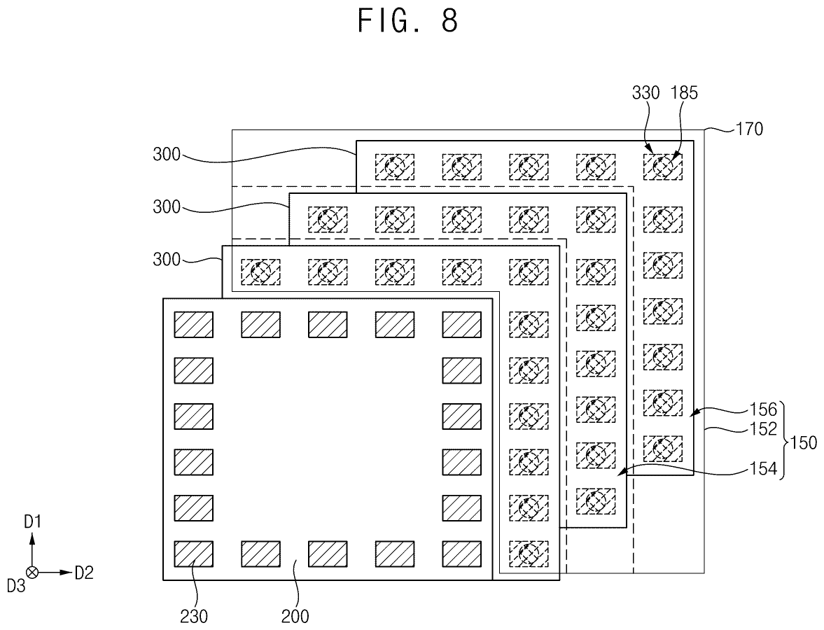

FIG. 8 is a bottom view illustrating a semiconductor chip stack structure and an interposer included in a semiconductor package in accordance with example embodiments, which may correspond to FIG. 2.

Referring to FIG. 8, the second semiconductor chips 200 included in the semiconductor chip stack structure may be stacked in a cascade shape on the first semiconductor chip 200, however, unlike those of FIGS. 1 and 2, the second semiconductor chips 200 may be arranged to be offset with each other not only in the second direction D2 but also in the first direction D1.

Thus, respective sidewalls in the first and second directions D1 and D2 of each of the second semiconductor chips 300 may not be aligned with corresponding sidewalls in the first and second directions D1 and D2 of other ones of the second semiconductor chips 300 thereunder, and an end portion in each of the first and second directions D1 and D2 of each of the second semiconductor chips 300 may not overlap the other ones of the second semiconductor chips 300 in the third direction D3.

The interposer 170 may have an “L” shape in a plan view or in a bottom view, corresponding to the shape of the semiconductor chip stack structure, and each of the third to fifth insulating interlayers 152, 154 and 156 included in the semiconductor chip stack structure may have an “L” shape in a plan view or in a bottom view.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of the claims.

What is claimed is:

1. A semiconductor package comprising:
a package substrate;
a semiconductor chip stack including:
a first semiconductor chip on the package substrate; and
second semiconductor chips stacked on the first semiconductor chip in a vertical direction, end portions in a first horizontal direction of the second semiconductor chips not being aligned with each other in the vertical direction;
an interposer between the package substrate and the semiconductor chip stack, the interposer at least partially overlapping the semiconductor chip stack in the first horizontal direction and including a wiring structure; and
a molding member on the package substrate and covering the semiconductor chip stack and the interposer,
wherein the package substrate includes a hole extending in the vertical direction through a portion of the package substrate between the first semiconductor chip and the interposer, and
wherein the molding member at least partially fills the hole.

2. The semiconductor package according to claim 1, wherein the end portion in the first horizontal direction of a first one of the second semiconductor chips protrudes in the first horizontal direction from the end portion in the first horizontal direction of second ones of the second semiconductor chips that are disposed under the first one of the second semiconductor chips.

3. The semiconductor package according to claim 2, wherein the interposer includes insulating interlayers stacked in the vertical direction, and
wherein a planar area of a first one of the insulating interlayers is less than a planar area of second ones of the insulating interlayers that are disposed under the first one of the insulating interlayers.

4. The semiconductor package according to claim 3, wherein each of the insulating interlayers at least partially overlaps the first semiconductor chip or one of the second semiconductor chips in the first horizontal direction.

5. The semiconductor package according to claim 4, wherein each of the insulating interlayers at least partially overlaps one of the second semiconductor chips in the vertical direction.

6. The semiconductor package according to claim 2, wherein the interposer has a staircase shape including steps arranged in the first horizontal direction, and
wherein each of the steps extends in a second horizontal direction crossing the first horizontal direction.

7. The semiconductor package according to claim 1, wherein:
the package substrate includes first and second conductive pads at an upper portion thereof,
the first semiconductor chip includes a third conductive pad at a lower portion thereof, and
the semiconductor package further comprises:
a first conductive connection terminal disposed between and contacting the first and third conductive pads; and
a second conductive connection terminal disposed between and contacting the second conductive pad and the wiring structure.

8. The semiconductor package according to claim 7, further comprising:
a first underfill between the package substrate and the first semiconductor chip, the first underfill contacting a sidewall of the first conductive connection terminal; and
a second underfill between the package substrate and the interposer, the second underfill contacting a sidewall of the second conductive connection terminal.

9. The semiconductor package according to claim 8, wherein the hole extends through a portion of the package substrate between the first and second underfills.

10. The semiconductor package according to claim 7, wherein each of the second semiconductor chips includes a fourth conductive pad at a lower portion thereof, and
wherein the semiconductor package further comprises a third conductive connection terminal on the interposer, the third conductive connection terminal disposed between and contacting the wiring structure and the fourth conductive pad.

11. The semiconductor package according to claim 1, wherein the semiconductor chip stack further includes:
a first adhesion layer between the first semiconductor chip and a lowermost one of the second semiconductor chips; and
a second adhesion layer between the second semiconductor chips.

12. The semiconductor package according to claim 11, wherein the first adhesion layer includes non-conductive paste (NCP) or non-conductive film (NCF), and
wherein the second adhesion layer includes die attach film (DAF).

13. The semiconductor package according to claim 11, wherein each of the first and second adhesion layers includes DAF.

14. The semiconductor package according to claim 1, wherein the molding member has a zig-zag shape formed between the semiconductor chip stack and the interposer and extending from the hole.

15. A semiconductor package comprising:
a package substrate;
a first conductive bump on the package substrate;
a semiconductor chip stack including:
a logic chip on the first conductive bump;
memory chips stacked on the logic chip in a vertical direction, end portions in a horizontal direction of the memory chips not being aligned with each other in the vertical direction;
a first adhesion layer disposed between and contacting the logic chip and a lowermost one of the memory chips, the first adhesion layer including a first adhesive material; and
a second adhesion layer disposed between and contacting the memory chips, the second adhesion layer including a second adhesive material different from the first adhesive material;
a second conductive bump spaced apart from the first conductive bump in the horizontal direction on the package substrate;
an interposer between the second conductive bump and the semiconductor chip stack, the interposer at least partially overlapping the semiconductor chip stack in the horizontal direction and including a wiring structure;
a first underfill between the package substrate and the semiconductor chip stack, the first underfill covering a sidewall of the first conductive bump;
a second underfill between the package substrate and the interposer, the second underfill covering a sidewall of the second conductive bump; and
a molding member on the package substrate and covering the semiconductor chip stack, the interposer, and the first and second underfills.

16. The semiconductor package according to claim 15, wherein the first adhesive material includes non-conductive paste (NCP) or non-conductive film (NCF), and
wherein the second adhesive material includes die attach film (DAF).

17. The semiconductor package according to claim 15, wherein:
the end portion in the horizontal direction of a first one of the memory chips protrudes in the horizontal direction from the end portion in the horizontal direction of second ones of the memory chips that are disposed under the first one of the memory chips,
the interposer includes insulating interlayers stacked in the vertical direction, and
a planar area of a first one of the insulating interlayers is less than a planar area of second ones of the insulating interlayers that are disposed under the first one of the insulating interlayers.

18. The semiconductor package according to claim 17, wherein each of the insulating interlayers at least partially overlaps the logic chip or one of the memory chips in the horizontal direction, and
wherein each of the insulating interlayers at least partially overlaps one of the memory chips in the vertical direction.

19. A semiconductor package comprising:
a package substrate structure;
a first conductive bump on the package substrate structure;
a semiconductor chip stack structure including:
a first semiconductor chip on the first conductive bump;
second semiconductor chips stacked on the first semiconductor chip in a vertical direction, end portions in a horizontal direction of the second semiconductor chips not being aligned with each other in the vertical direction;
a first adhesion layer disposed between and contacting the first semiconductor chip and a lowermost one of the second semiconductor chips; and
a second adhesion layer disposed between and contacting the second semiconductor chips;
a first underfill member between the package substrate structure and the semiconductor chip stack structure, the first underfill member covering a sidewall of the first conductive bump;
a second conductive bump spaced apart from the first conductive bump in the horizontal direction on the package substrate structure;
an interposer between the second conductive bump and the semiconductor chip stack structure, the interposer at least partially overlapping the semiconductor chip stack structure in the horizontal direction and including a wiring structure;
a second underfill member between the package substrate structure and the interposer, the second underfill member covering a sidewall of the second conductive bump;
a third conductive bump between the interposer and the semiconductor chip stack structure; and
a molding member on the package substrate structure and covering the semiconductor chip stack structure, the interposer, the first and second underfill members, and the third conductive bump,
wherein the package substrate structure includes a hole extending in the vertical direction through a portion of the package substrate structure between the first semiconductor chip and the interposer, and
wherein the molding member at least partially fills the hole.

20. The semiconductor package according to claim 19, wherein:
the end portion in the horizontal direction of a first one of the second semiconductor chips protrudes in the horizontal direction from the end portion in the horizontal direction of second ones of the second semiconductor chips that are disposed under the first one of the second semiconductor chips,
the interposer includes insulating interlayers stacked in the vertical direction, and
a planar area of a first one of the insulating interlayers is less than a planar area of second ones of the insulating interlayers that are disposed under the first one of the insulating interlayers.
